(19) United States
(12) Patent Application Publication
(10) Pub. No.: US 2022/0081801 A1
(43) Pub. Date: Mar. 17, 2022

(54) MANUFACTURE OF LAB GROWN DIAMONDS

(71) Applicant: LUSIX LTD., Nes Ziona (IL)

(72) Inventor: Yosef YAYON, Rehovot (IL)

(73) Assignee: LUSIX LTD., Nes Ziona (IL)

(21) Appl. No.: 17/535,626

(22) Filed: Nov. 25, 2021

Related U.S. Application Data
(63) Continuation-in-part of application No. PCT/IB2020/055065, filed on May 28, 2020.

(30) Foreign Application Priority Data
May 31, 2019 (GB) 1907817.9

(51) Int. Cl. C30B 29/04; C30B 25/10; C30B 25/16; C30B 30/00; C23C 16/27; C23C 16/52; C23C 16/511; C23C 16/46; C30B 29/66

(52) U.S. Cl. CPC C30B 29/04; C30B 25/105; C30B 25/165; C30B 30/00; C30B 29/66; C23C 16/279; C23C 16/52; C23C 16/511; C23C 16/463; C23C 16/274

(57) ABSTRACT

A method is disclosed for manufacturing lab grown diamond material by plasma enhanced chemical vapour deposition (PECVD). A substrate is exposed to a plasma containing carbon species while supported within a recess in a holder, resulting in a single crystal diamond (SCD) growing on the substrate while polycrystalline diamond (PCD) is deposited on the substrate holder. The relative rate of growth of the single crystal diamond on the substrate and the polycrystalline diamond on the surface of the holder is set, by control of at least one of the applied energy, cooling of the substrate holder and the chemical composition of the process gases, such that the single crystal diamond grown on the substrate protrudes above the surface of the holder and is constrained not to increase or to reduce in cross sectional area with increased distance from the surface of the holder by simultaneous growth of a polycrystalline diamond layer on the surface of the holder.

### CROSS RELATED APPLICATIONS

This application is a Continuation-In-Part (CIP) of International Application Number PCT/IB2020/055065, filed on May 28, 2020, which claims priority from GB Patent Application Number 1907817.9, filed on May 31, 2019. The entire disclosures of all the aforementioned applications are incorporated by reference herein for all purposes as if fully set forth herein.

### FIELD

The present disclosure relates to the manufacturing of synthetic diamond material, also known as laboratory grown diamonds. In particular, the present disclosure relates to an apparatus and method relying on chemical vapour deposition, and to diamonds prepared using the same.

### BACKGROUND

As natural diamonds are becoming increasingly scarce with time and often associated with concerns regarding the conditions of their mining and commercialization, numerous attempts to produce such precious gemstone synthetically have been reported. Diamonds are not only of interest as gemstones, but are also used in industry in view of their physical properties. In particular, diamond is the hardest known material, has the highest known thermal conductivity, and greatest transparency to electromagnetic (EM) radiation. Diamonds are also the best semiconductor material for use in high power electronics.

Methods of preparing such diamond materials (also called lab grown diamonds) include chemical vapour deposition (CVD) processes, which are now well known in the art. Such processes, which preferably intend to result in single crystal diamonds (SCDs), can, for instance, be achieved by Plasma Enhanced Chemical Vapor Deposition (PECVD).

In PECVD, a single crystal seed of any suitable form of diamond is disposed (typically in a suitable holder) in a chamber adapted to sustain low pressures (e.g., of tens of thousands of Pascal) and high temperatures (e.g., of up to 1300° C.), a mixture of gases supplying atoms needed for the diamond growth (e.g., methane as a source of carbon) or for its facilitation (e.g., hydrogen to selectively etch off non-diamond carbon) is fed to the chamber in a controlled manner and a microwave radiation generator creates a hemisphere-shaped plasma in close proximity above the seed, allowing its growth as a result of the diamond layers deposited thereon. Such devices further include a coupling configuration for feeding the microwaves from the microwave generator into the chamber (which can also be referred to as a plasma chamber); a gas flow system for feeding the process gases (selected for example from CH₄, C₂H₂, C₂H₄, C₂H₆, CO₂, H₂, O₂, N₂, NO₂, N₂O, Ar, and from any other source of carbon atoms and hydrogen atoms, and combinations thereof) into the plasma chamber and removing them in a controlled manner; a temperature control system for controlling the temperature of the diamond growth surface; a pressure control system for controlling the pressure in the plasma chamber. The chamber may be made of stainless steel and may be provided with quartz viewports.

The synthesis characteristics may depend on a number of factors, which include for instance, the power and frequency of the microwave, the geometry of the holder and the chamber and their relative positioning, the temperature of the diamond growth surface, the gas composition and pressure, and such known parameters, which may additionally affect the properties of the product which is obtainable. The product resulting from such a reaction needs further processing (e.g., annealing, cutting, polishing, etc.) before it may look as a finished gemstone, as used, for instance, in jewellery. Therefore, while the terms of rough or raw diamonds are typically associated with the natural gemstone, these terms may also be used to refer to the end-product of a PECVD synthesis, before any desired post-growth processing step is performed. Generally raw lab grown diamonds, and in particular rough PECVD-grown diamonds have a cubic or cuboid shape, corresponding to the sequential deposition of carbon layers on seeds having a generally square circumference. In some cases, the growth of the diamond is interrupted and/or reinitiated with new parameters or relative positioning of the seed to overcome limitation of the PECVD device or process. In particular cases, not only is the growth done in steps, but the growing diamond may require being processed (cut and/or polished) between the steps and repositioned in the holder.

It can be appreciated that a number of considerations should be taken into account to achieve a successful industrial process. It is noted that a number of reports concerning synthesis of diamonds by PECVD are in fact limited to experimental implementation of such concepts and are of dubious relevance to commercial production.

In conventional flat holders, the seeds are disposed on the surface of the holder and the diamond grows above the growth area of the seed or in a manner mildly expanding out of the seed area. A polycrystalline diamond (PCD) layer grows on the (lateral/top) edges of the cuboid as the single crystal diamond (SCD) grows. For jewellery purpose, the gems are typically symmetrical, hence the seeds are usually shaped as squares, building up a cuboid. However, this term should not be construed as limiting the seeds to squares of identical edge length, nor to ideal cubes, the term being rather used to refer to shapes which may have slopes between the seed and the outermost deposited carbon layer forming an angle of about 90° with the base, or a mildly obtuse one, typically of no more than 100°.

This outcome is schematically depicted in the side view of FIG. 1, where two diamond seeds 102 and 104 are illustrated on top of a seed-holder 110. As the synthesis proceeds, layers of diamond are deposited on each of the seeds, building up an essentially cubic shape, as represented by 106, or a more cuboid one, as represented by 108, the walls expanding out of the original area of the seed as layers are formed and the diamond grows farther apart from the surface 118 of the holder. A PCD film 112 growing on the surface 118 of the holder 110, on the sides of the diamond and surrounding the top rim of the upper surfaces of the lab-grown diamonds are also shown. A photographic image of an exemplary CVD grown diamond (following partial removal of PCD residues) traditionally lab-grown above a surface of a holder is shown in FIG. 9. In some cases, thick diamond crystals can grow in various shapes due to the different growth rate of the different crystallographic orientations in different growth conditions (see F. Silva et al, “Geometric modeling of homoepitaxial CVD diamond growth—I. The {100}{111}{110}{113} system).

In some holders, as described for example in WO2018/087110 and schematically illustrated in the side view of FIG. 2, the seeds 202 and 204 can be disposed at the bottom of a pocket 212′ or 212″ recessed into the top surface 218 of the holder 210 to achieve a better temperature uniformity over the growth area of the seed. Typically, diamonds are grown in such pockets (having a base 214 and expanding walls 216) in a manner ensuring that the top surface of the last deposited layer, i.e. the growth surface, does not protrude above the holder surface (represented by a dashed line over the pocket openings). A PCD layer 222 on top of the surface of the holder tends to grow thick and eventually the PCD layer starts converging and attempts to join onto the single crystal diamond (SCD) surface. This constricts the growth of the diamond as schematically represented by shapes 206 and 208 confined within the volume of the recessed pocket 212. At this point, the common practice is that the growth process needs to be stopped and the holder needs to be cleaned in order to enable a smooth growth process. In such an intermittent conventional growth process the lateral faces of the grown crystal are oriented parallel to the diamond crystallographic orientations, such as {100}, {110}, {111}, {113} and the like. The final faces constituting the shape of the grown diamond will be defined by the relative growth rate of each crystallographic orientation.

In order to prevent the diamond from growing above the surface of the holder, it has been proposed to deepen the recessed pockets (increasing the growing zone) by a) driving down the base 214 of the pocket 212 or b) adding hollowed discs (not shown) over the holder 210, building-up higher/deeper walls to the recessed pocket with each added disc, as the synthesis proceeds.

### SUMMARY

Contrary to the known use of recessed pockets, in the present invention the single crystal diamond is grown above the surface of the holder, despite the fact that this takes place in parallel with production of PCD on the surface of the holder. The invention is predicated on the discovery that the shape of a SCD protruding from the holder can be modified by suitable control of the growth rate of the PCD build-up on the surface of the holder relative to the growth rate of the desired SCD. Such controlled relative growth rate enables the manufacturing of lab grown diamond material in a continuous, uninterrupted, process. This advantageously results in SCD diamonds of relatively significant dimensions being devoid of layers, as typically detectable in diamonds grown step-wisely. The presence, or absence, of layers in a lab grown diamond is typically detected following the elimination of the PCD surrounding the core SCD and optionally following separation of the seed. In some extreme cases, conventional preparation of SCD may result in the appearance of layers (in the growing direction) being visually detectable by the naked eye. Alternatively, layers may be detected by standard methods for microscopic or spectroscopic analysis. Moreover, the lateral faces of a SCD diamond grown according to the present invention do not have to be oriented parallel to the diamond crystallographic orientations and in general can be oriented in any orientation defined by the growth of the surrounding PCD layer.

According to an aspect of the invention, there is provided a method of manufacturing lab grown diamond material by plasma enhanced chemical vapour deposition (PECVD), which comprises:

placing in a recessed pocket of a holder located in a chemical vapour deposition chamber a single crystal diamond substrate to act as a seed,

establishing within the chamber a plasma containing carbon species, by introducing process gases into the chamber and heating the gases by electrically generated energy, to cause carbon to be deposited as a single crystal diamond (SCD) on the substrate to form a lab grown diamond and in polycrystalline diamond (PCD) form on the substrate holder,

growing SCD on the substrate sufficiently to cause a part (e.g., a top surface) of the lab grown diamond to protrude from the pocket, and

setting the relative rate of growth of the SCD on the substrate and the PCD on the surface of the holder, by control of at least one of (i) an applied energy, (ii) cooling of the substrate holder and (iii) a chemical composition of the process gases, such that the PCD layer is grown on the surrounding surface of the holder at such a rate as to lie, at all times, at a height above the surface of the recessed pocket in the holder that is at least as high as the (top) surface of the SCD, whereby the PCD layer entirely surrounds the SCD grown on the substrate and constrains lateral growth of the SCD to prevent an increase of a cross-sectional area of a part of the lab grown diamond protruding out of the recessed pocket. The PCD layer surrounding the lateral faces of the SCD restricts the SCD lateral growth and determines its final shape.

In some embodiment, placing a seed for the SCD includes providing a chamber for PECVD and providing a holder adapted to be located in such a chamber, the holder including one or more recessed pockets.

In an embodiment of the invention, the constraining of the lateral growth of the single crystal diamond results in a reduction in the cross-sectional area of the part of the single crystal diamond protruding out of the recessed pocket with increasing distance from the holder.

The constraining of the lateral growth of the single crystal diamond when its cross section in the part protruding out of the recessed pocket is not increasing or is alternatively decreasing (i.e. the rate of decrease of the cross section) may be such that the height of the synthesised single crystal diamond, as measured from the substrate, is between 40% and 80%, or between 50% and 70%, or substantially 60%, of the maximum width of the substrate.

While the heating of the gases may be carried out by a spark discharge, in an embodiment of the invention, the energy is applied in the form of EM energy at a frequency in the microwave range, i.e. having a wavelength between 1 mm and 1 m.

According to a second aspect of the invention, there is provided a PECVD system for manufacturing a lab grown single crystal diamond (SCD) material via chemical vapour deposition, the system comprising:
a) a microwave generator configured to generate microwaves at a frequency f;
b) plasma chamber comprising a base, a top plate, and a side wall extending from said base to said top plate defining a resonance cavity for supporting a microwave resonance mode between the base and the top plate;
c) a microwave coupling configuration for introducing microwaves from the microwave generator into the plasma chamber;
d) a gas flow system for feeding process gases into the plasma chamber and removing exhaust gases therefrom, the gas flow system including a gas flow controller for controlling a composition of the process gases;
e) a substrate holder disposed in the plasma chamber and comprising an outer surface and at least one supporting surface for supporting the seed, the surface supporting the seed being recessed with respect to the outer surface of the holder;
f) a pressure control system for regulating the pressure within the plasma chamber;
g) a cooling system for regulating the temperature of the substrate holder; and
h) a control system for setting a relative rate of growth of the SCD on the substrate and a polycrystalline diamond (PCD) layer on the surface of the holder, by control of at least one of (i) an applied energy, (ii) cooling of the substrate holder and (iii) a chemical composition of the process gases, such that the PCD layer is grown on the surrounding surface of the holder at such a rate as to lie, at all times, at a height above the surface of the recessed pocket in the holder that is at least as high as the surface of the SCD, whereby the PCD layer entirely surrounds the SCD grown on the substrate and constrains lateral growth of the SCD so as to prevent an increase in cross sectional area of the part of the lab grown diamond protruding from the recessed pocket.

In some embodiments, the control system is operative to set the relative rate of growth of the single crystal diamond on the substrate and of the polycrystalline diamond layer on the surface of the holder in such a manner that the SCD is constrained by the surrounding PCD layer to cause the cross sectional area of the part of the single crystal diamond protruding beyond the recessed surface of the holder to decrease with increasing distance from the holder. The control system is adapted to set predetermined operating conditions for each of the sub-systems of the apparatus of the invention and suitable for monitoring said parameters in operation. For non-limiting illustration, such a system may control of at least one of the energy of the microwave generator, the microwave energy controlling in turns e.g., the shape of the plasma and the temperature of the process gases in the chamber; the cooling of the substrate holder (hence a temperature gradient between the process gases and the holder, the seed or the growing diamond materials); and the chemical composition of the process gases.

According to a third aspect of the invention, there is provided a single crystal diamond (SCD) manufactured via plasma enhanced chemical vapour deposition, inter alia according to a method of the present invention and/or using a PECVD apparatus or system according to the present teaching, the single crystal diamond upon completion of chemical vapour deposition having a truncated first shape of which the cross sectional area decreases, or does not increase, with increasing distance from a flat base formed by a surface of a seed from which the SCD material is grown and having a truncated surface substantially parallel to the base, or a second shape having the form of a two back to back truncated tapered shapes that share a common base, the seed from which the SCD material is grown forming a flat truncated surface of one of the two truncated tapered shapes.

In some embodiments, the first shape of the CVD synthesized lab grown SCD material, or the back-to-back truncated tapered shapes are each, a truncated pyramid having a polygon base and truncated surface.

According to a fourth aspect of the invention, there is provided a diamond material comprising at least one CVD synthesized lab grown single crystal diamond (SCD) material formed by chemical vapour deposition on a surface of at least one seed, the SCD material grown on each seed being surrounded by a polycrystalline diamond (PCD) material on all lateral faces, the SCD material grown on each seed having either a first shape of which the cross sectional area decreases, or does not increase, with increasing distance from the respective surface of the seed and having a truncated surface substantially parallel to the base, or a second shape formed of two back to back truncated tapered shapes that share a common base, the seed from which the SCD material is grown forming a flat truncated surface of one of the two truncated tapered shapes.

Other aspects and features of the invention are hereinafter set forth below, within the description of the drawings.

### BRIEF DESCRIPTION OF THE DRAWINGS

Some embodiments of the disclosure will be described, by way of example, with reference to the accompanying figures, where like reference numerals or characters indicate corresponding or like components. The description, together with the figures, makes apparent to a person having ordinary skill in the art how some embodiments of the disclosure may be practiced. The figures are for the purpose of illustrative discussion and no attempt is made to show structural details of an embodiment in more detail than is necessary for a fundamental understanding of the disclosure. For the sake of clarity and convenience of presentation, some objects depicted in the figures are not necessarily shown to scale.

In the Figures:

FIG. 1 schematically illustrates a side view of a substrate holder as disclosed in prior art publications relating to holders having a planar surface upon which seeds can be supported.

FIG. 2 schematically illustrates a cross-section view of a substrate holder as disclosed in prior art publications relating to holders having recessed pockets within which seeds can be inserted.

FIG. 3 schematically illustrates a cross-section view of a substrate holder having recessed pockets but used in a process in which the single crystal diamonds continue to grow outside the pockets.

FIG. 4 is a view similar to that of FIG. 3, but in which the rate of deposition of PCD is increased resulting in the single crystal diamond having a tapering rather than an expanding cross section.

FIG. 5 is a view similar to FIGS. 3 and 4 but in which the rate of deposition of the PCD is greater than in FIG. 3 but less than in FIG. 4.

FIG. 6 schematically illustrates a top view of a substrate holder comprising more than one recessed pocket.

FIG. 7A is a schematic perspective view of a diamond having the shape of a truncated pyramid.

FIG. 7B is a schematic side view of a diamond as shown in FIG. 7A.

FIG. 8 is a schematic representation of a plasma enhanced chemical vapour deposition apparatus capable of implementing the present invention.

FIG. 9 is a photographic image of a lab-grown cuboid, as may be obtained by methods of the prior art.

FIG. 10 is a photographic image of a diamond manufactured by the method of the invention.

FIG. 11 illustrates the polish yield obtainable when seeking to polish a round shape diamond from a prior art cubic lab-grown rough diamond.

FIG. 12 illustrates the polish yield obtainable when seeking to polish a round shape diamond from a diamond manufactured by the method of the invention.

FIG. 13 illustrates the polish yield obtainable when seeking to polish a cushion shape diamond from a prior art cubic lab-grown rough diamond.

FIG. 14 illustrates the polish yield obtainable when seeking to polish a cushion shape diamond from a diamond manufactured by the method of the invention.

### DETAILED DESCRIPTION

In the present invention, the shape of the synthesised single crystal diamond is optimised by controlling the operating parameters that determine the relative rate of growth of the SCD and the PCD. Such control may be by open or closed loop. These growth rates are dependent on the temperatures of the plasma, the substrate, and the substrate holder as well as the chemical composition of the gases and they can therefore be controlled by varying the energy applied to generate the plasma, the cooling of the substrate holder and the composition of the gases, which may typically include methane, hydrogen, oxygen and nitrogen.

If the growth rate of the SCD is greater than the growth rate of the PCD, the rough diamond may have a shape expanding out of the original lateral shape of the seed. Taking for illustration a square seed and a recessed pocket, then a rough diamond continuing to grow from such a recessed pocket above holder-surface would roughly have a larger top surface than its original seed top surface, as shown in FIG. 3. This figure shows a side view of a holder 310 with recessed pockets 312, which may be similar to previously described holder 210 and pockets 212. Diamond seeds 302, 304 are illustrated in the base 314 of the pocket 312 recessed into the top surface 318 of the holder 310, and the diamonds that may grow thereupon are represented by the shapes 306 and 308. As its growth is no longer confined to the inner volume of the pocket at some point the SCD will pass the upper surface of the PCD film 322 and will continue to expand laterally.

If, on the contrary, the growth rate of the PCD is greater than or approximately equal to the growth rate of the SCD, the PCD film on the top of the holder will converge until eventually it will almost or fully close over the recessed pocket preventing lateral growth of the SCD. Diamonds grown by such a process are shown in FIGS. 5 and 4, respectively.

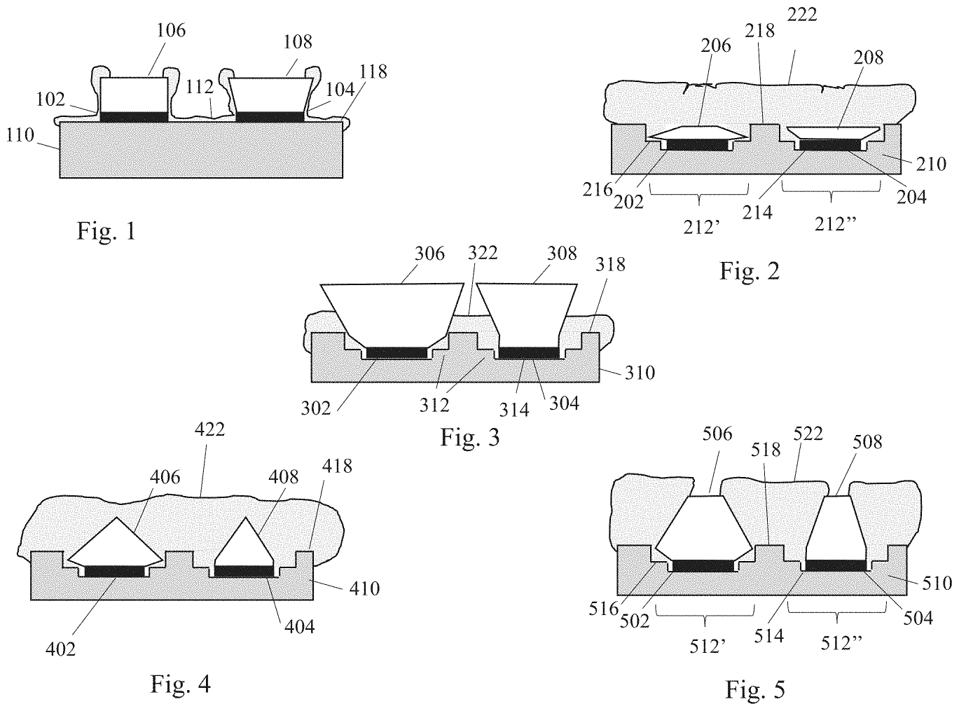

PECVD grown diamonds prepared as described in FIG. 1 or FIG. 2, may enable a polish yield (also termed a polishing efficiency) of about 25-35%, depending on the shape of the rough diamond and the desired shape of the cut gemstone.

In an embodiment of the invention, the growth rate of the PCD is set to approximately the same growth rate as the SCD. This results in a rough diamond having a shape particularly suitable for the preparation of gemstones, minimizing the waste so as to increase the polish yield to up to 40-60%. Taking again for illustration a square seed and a holder recessed pocket having pyramidal inner walls, setting conditions capable of maintaining the growth rate of the PCD and of the SCD close to one another, would allow the synthesis of a rough diamond appearing as two cropped pyramids attached to one another by their basis. Generally, the bottom pyramid having built-up within the pocket is much smaller than the upper one having grown above the surface of the holder. The lateral faces of the pyramid shaped diamond do not have to coincide with one of the diamond crystallographic orientations and can be in any arbitrary angle defined by the surrounding PCD. Thus, while an SCD grown in a conventional method lacking a surrounding PCD according to the present teachings may result in an SCD material having side faces in a crystallographic orientation selected from {100}, {110}, {111 }, and {113 }, SCD diamonds prepared by the present method may additionally assume different orientations other than {100}, {110}, {111 }, and {113 }.

Depending on the configuration of the recessed pocket(s) and/or on the relative growth rate of the PCD and the SCD, the rough diamond stone may alternatively appear as a single cropped pyramid, the apex of which being a top surface.

FIG. 5 schematically illustrates the latter scenario. The latter figure shows a holder 510 with recessed pockets 512′ and 512″, which may be similar to previously described holder 210 and pockets 212. Diamond seeds 502, 504 are illustrated in the base 514 of the pockets and the diamonds that may grow thereupon are represented by shapes 506, 508. As under these growth rates conditions, the height of the SCD diamond is similar to the height of PCD film 522, the build-up of the PCD on the holder surface 518 serves in manner similar to the inner walls of the pocket to constrain the cross section of the SCD diamond. While the recessed pockets 512 are depicted in the figure as being “double pockets”, twice recessed with respect to the surface of the holder, the smallest underneath pocket facilitating the holding of the seed, this should not be construed as limiting. Recessed pockets 512 can alternatively be “single pockets” upon the base 514 of which a seed can be attached.

Thus, while conventional PECVD methods may result in rough diamonds either having a cubic or cuboid shape when using a planar holder (as illustrated in FIG. 1) or having a truncated tapered shape (as illustrated in FIG. 2), the present teachings provide, in one embodiment, a rough diamond having a shape similar to a bipyramid, a bicone, or any form resembling the joining of two congruent truncated tapered shapes base-to-base (as illustrated in FIG. 5). For simplicity, all such shapes shall be referred to as bipyramids or bipyramidal regardless of the exact shape of the rough diamond, and this term encompasses herein diamonds having approximately a circular cross-section (or projection), an ellipsoidal cross-section, or a polygonal cross-section. When the growth rate of the SCD is not sufficiently similar the growth rate of the PCD as herein disclosed, diamonds prepared according to the present teachings may also result in rough diamonds having a more tapered shape, as shown in FIG. 4 or a less tapered shaped. In the manufacture of diamond of gemstone quality, the optimum aspect ratio of a diamond is when its depth is around 60% of its minimum width, and it therefore desirable to set the relative rate of deposition of SCD and PCD such that the depth of deposition of SCD is between 40% and 80% of the width of the seed substrate.

In order for the growth rate of the SCD and of the PCD to be sufficiently similar to produce rough diamonds having a bipyramidal shape, in an embodiment of the invention the difference of temperature between the seed within the recessed pocket and the surface of the holder should be between 50° C. and 200° C., or between 75° C. and 150° C., or between 75° C. and 125° C. Typically, the temperature of the holder is lower than the temperature of the seed.

These temperatures can be monitored in situ by a pyrometer and may relate to average temperatures. While the temperature of a seed can be measured at a single point for each seed to be sufficiently representative, such articles having a relatively small size and good thermal conductivity, the temperature of a holder, in particular if including a number of recessed pockets each being at a different position with respect to the plasma formed by the microwave generator, may need to be measured at several points.

In such embodiments, where the temperature of the growth surface is measured at two or more points for a single seed, a difference in temperature between at least two of the points of measurements can be of 25° C. or more, of 30° C. or more, of 35° C. or more, of 40° C. or more, or of 45° C. or more. Depending on the size of the growth surface, its evolving shape, and operating conditions, in some embodiments, at least two of the points of measurements may display a temperature difference of up to 200° C., or up to 150° C., or up to 100° C.

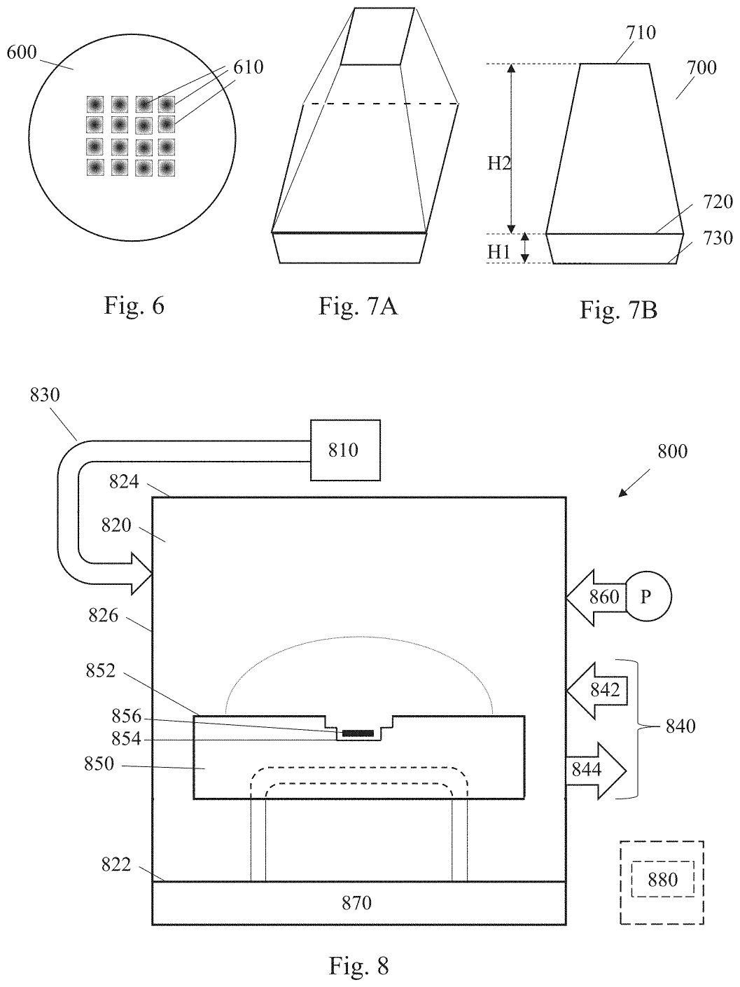

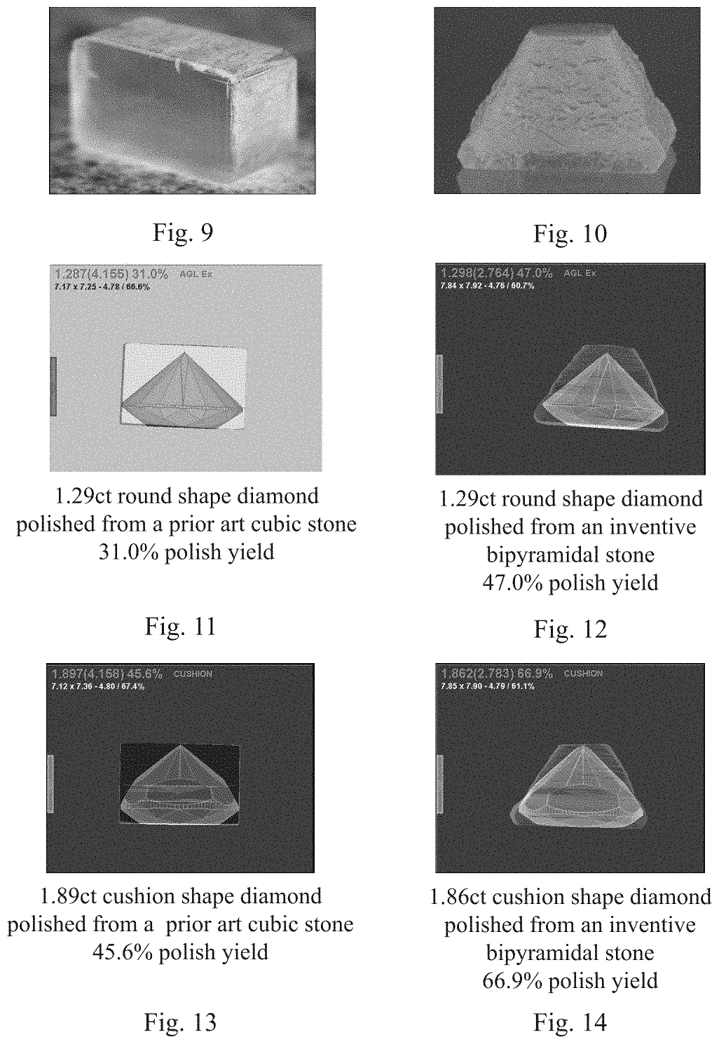

A top view of holder 600 having sixteen recessed pockets 610 is illustrated in FIG. 6. A holder suitable for an apparatus, system and method according to the present teachings may accommodate any other number of recessed pockets, and the sixteen pockets illustrated in the figure should not be construed as limiting. While in some embodiments, the seeds may be placed each in a recessed pocket without any particular attachment, in alternative cases the seeds may be glued or brazed to the holder. Without wishing to be bound by theory, this may improve the thermal conductivity of the seed-holder interface and/or facilitate a control of the temperature difference between the seed and the holder.

The temperature of the holder in operation should preferably be uniform over its entire surface, to obtain relatively even growth conditions. As the reaction temperature is elevated (typically above 900° C.), the temperature of the holder is deemed uniform if a maximal temperature difference between any two points on the holder does not exceed 200° C., and preferably is of less than 150° C., less than 100° C., or less than 50° C.

A PECVD apparatus or system of an aspect of the invention comprises a microwave generator; a plasma chamber comprising a base, a top plate, and a side wall extending from said base to said top plate defining a resonance cavity for supporting a microwave resonance mode between the base and the top plate; a waveguide for introducing microwaves from the microwave generator into the plasma chamber; a gas flow system for feeding process gases into the plasma chamber and removing exhaust gases therefrom, the gas flow system including a gas flow controller for controlling a composition of the process gases; a substrate holder disposed in the plasma chamber and comprising an outer surface and at least one supporting surface for supporting a substrate of single crystal diamond to serve as a seed, the surface supporting the seed being recessed with respect to the outer surface of the holder; a pressure control system for regulating the pressure within the plasma chamber; and a cooling system for regulating the temperature of the substrate holder; wherein a control system is further provided for setting the relative rate of growth of SCD on the substrate and polycrystalline diamond (PCD) on the surface of the holder by control of at least one of the microwave energy, the cooling of the substrate holder and the chemical composition of the process gases, such that a single crystal diamond is grown on the substrate that protrudes above the surface of the holder and is constrained to reduce in cross sectional area, or at least not to increase in cross sectional area, with increased distance from the surface of the holder by simultaneous growth a PCD layer on the surface of the holder.

In an alternative aspect of the invention, an electric arc may be used to produce a plasma in place of microwave energy.

If microwaves are employed, they may be generated by one or more generators, such as magnetrons or solid-state microwave sources. In embodiments wherein multiple microwave sources are present, the microwave sources may be independently controllable.

In one embodiment, the microwave generator and any microwave source it may include (e.g., magnetron or solid-state) can generate single or fixed frequency microwave (e.g., supplying a continuous wave (CW) microwave power at 2.45 GHz or 915 MHz). In one alternative embodiment, the microwave sources are configured to pulse the microwave power coupled into the plasma chamber at a pulse frequency in a range 10 Hz to 1 MHz, 100 Hz to 1 MHz, or 1 kHz to 100 kHz.

In one embodiment, when the plasma chamber is cylindrical, microwaves are coupled into the plasma chamber by a dielectric window, a coaxial waveguide, and a waveguide plate comprising a plurality of apertures disposed in an annular configuration. Coupling of the microwave sources to the plasma chamber can be direct or indirect, and include for instance, mechanical coupling, magnetic coupling and electric coupling.

In one embodiment, the gas flow system is configured to feed, in operation, at least two of the following process gases at the indicated gas flow rates: a) hydrogen (H₂) 200-2000 SCCM (standard cubic centimetre per minute); b) methane (CH₄) 4-20% of H₂; c) oxygen (O₂) 0-25% of CH₄; and d) nitrogen (N₂) 0-3% of CH₄.

In one embodiment, the substrate holder serves as a heat sink holder. The holder may additionally serve as heat flow pattern regulator and be configured to increase temperature uniformity. The substrate holder is made of a material compatible with the operational conditions of the process (e.g., chemically inert, plasma resistant, heat resistant, etc.). The holder may be made of molybdenum or any other type of material having high thermal conductivity, such as molybdenum-tungsten alloys or ceramics having high melting points above process temperature and a thermal conductivity comparable to that of molybdenum.

The holder, in one embodiment is movable by means a suitable actuator and is moved down at approximately the same speed as the growth rate so as to maintain the growth surface stationary in relation to the plasma and sensors monitoring the growth surface.

In one embodiment, the recessed seed supporting surface is a bottom surface of a seed supporting pocket, the pocket further comprising a top surface opposing the bottom surface in a longitudinal axis direction defined by the substrate holder, a base surface between the top surface and bottom surface, and one or more sidewalls extending between the base surface and the top surface, wherein: (i) the one or more sidewalls and the base surface define a cavity in the substrate holder, the cavity having a depth in the longitudinal axis direction extending between the base surface and the top surface, (ii) the cavity comprises a first recess in a lower portion of the cavity and a second recess in an upper portion of the cavity, (iii) the first recess is adjacent the base surface, and (iv) the second recess is directly above the first recess and extends a predetermined distance above the first recess to define a growth volume space in the cavity.

In one embodiment, the seed supporting surface at the base of the recessed pocket may serve to support more than one seed.

In one embodiment, the apparatus or system is constructed to sustain, in operation, a pressure of 15,000-60,000 Pascal. In one embodiment, the pressure controller is configured to maintain, in operation, a pressure of 15,000-60,000 Pascal.

In one embodiment, the apparatus or system is constructed to sustain and/or maintain, in operation, a temperature of 700-1400° C. compatible with the CVD process. In some embodiments, the temperature control system is configured to maintain, in operation, a difference in temperatures between the seed and the substrate holder such that their respective growth rates are similar.

In one embodiment, the temperature control system is configured for receiving a temperature measurement from a non-contact temperature measurement device and for controlling a temperature of the growth surface of the seed and/or a temperature of the substrate holder based upon the temperature measurements. The temperature can be modulated by either varying the heat applied to one surface (e.g., modifying parameters affecting the plasma, and heat generated thereby), and/or varying the cooling of one surface as compared to the other, hence in some embodiments the apparatus or system further comprises a cooling system (e.g., a circulating coolant, such as air or water) adjacent a surface to be relatively cooled, the cooling system being controlled by the temperature controller.

As the cooling system may be required to evacuate significant amount of heat generated by the plasma, cooling may be applied (in addition to the holder), to the microwave generator, the walls of the plasma chamber, and any other part of the apparatus or system known to benefit from such cooling. Cooling can be indirect or by direct contact with a coolant.

In a still further aspect, the invention provides a method of manufacturing lab grown diamond material via plasma enhanced chemical vapour deposition (PECVD), which comprises:
a) providing a seed adapted to make thermal contact with a seed holder, the seed having a growth surface suitable for the growth of the diamond material in a plasma enhanced reactor, the reactor including a microwave generator configured to generate microwaves, a plasma chamber defining a resonance cavity for supporting a microwave resonance mode and a microwave coupling configuration for feeding the microwaves from the microwave generator into the plasma chamber;
b) positioning the seed on a seed supporting surface of a substrate holder positioned within the plasma chamber so that plasma species can reach the diamond growth surface, the surface supporting the seed and the seed thereon being recessed with respect to an outer surface of the holder adjacent the microwave resonance;
c) feeding microwaves into the plasma chamber;
d) feeding process gases to the plasma chamber;
e) applying a controlled pressure to the plasma chamber;
f) measuring temperature of the growth surface of the diamond material and of the substrate holder to generate respective temperature measurements; and
g) forming lab grown diamond material on the seed while controlling a difference between the temperatures of the growth surface and of the substrate holder based upon the temperature measurements, so that a growth rate of the diamond material is similar (it does not have to be exactly equal) to a growth rate of a polycrystalline diamond that is concurrently formed in the method.

In some embodiments, the diamond material being grown by the aforesaid method includes a single crystal diamond and the relative growth of the single crystal diamond protruding out of the recessed pocket and of the polycrystalline diamond concurrently forming on the surface of the holder are such that lateral growth of the single crystal diamond is constrained by the surrounding polycrystalline diamond layer to prevent the cross sectional area of the part of the single crystal diamond protruding out of the recessed pocket from increasing with increasing distance from the holder. In one embodiment, the constraining of the lateral growth of the single crystal diamond results in a reduction in the cross-sectional area of the part of the single crystal diamond protruding out of the recessed pocket.

The carbon species found in the plasma may include carbon atoms, carbon molecules, carbon ions and carbon radicals.

In one embodiment, the seed (which can also be referred to as an SCD seed or an SCD chip) can be any piece of single crystal diamond including but not limited to industrial diamond, high temperature and high pressure (HPHT) synthesized diamond, gemstone diamond and/or natural diamond.

An SCD seed can define a geometry cut on any diamond surface plane and can be formed or utilized in any geometric shape and size. The seed may have a shape selected from a square, rectangle, circle, marquise, oval or heart.

In one embodiment, the seed dimensions include an edge length, an edge width or a diameter which lies in a range 50 mm to 120 mm, 60 mm to 120 mm, 70 mm to 110 mm, 80 mm to 110 mm, 90 mm to 110 mm, or 95 mm to 105 mm. In some embodiments, the seed has a thickness in a range 2.0 mm to 4.0 mm, or 2.5 mm to 3.5 mm. In alternative embodiments, the seed thickness may be in the range of 0.1mm to 1.5 mm, typically 0.3 mm.

In one embodiment, the microwave radiation is applied at a frequency of 2.45 GHz. In another embodiment, the microwave radiation is applied at a frequency of 915 MHz GHz.

In one embodiment, the microwave radiation is fed at a power such that the power density in terms of power per unit volume at the plasma is in a range of 40 to 400 W/ cm³.

In one embodiment, the process gases include methane, hydrogen, oxygen, carbon dioxide and nitrogen. The process gases may optionally comprise further components which may provide a desired property to the intended product. For example, the presence of selected species in the plasma may serve to impart a desired color to the SCD (e.g., boron may be added to the process gases to obtain blue diamonds).

In one embodiment, the hydrogen gas is fed to the plasma chamber at a flow rate within a range of 200 to 2000 SCCM (standard cubic centimetre per minute), or 200 to 1000 SCCM, or 300 to 800 SCCM, or 400 to 600 SCCM.

In one embodiment, the pressure within the plasma chamber is within a range of 10 kiloPascal (kPa) to 100 kPa, or 10 kPa to 60 kPa, or 15 kPa to 75 kPa, or 15 kPa to 50k Pa. For non-limiting illustration, the pressure applied to the plasma chamber may be of 25 kPa.

In one embodiment, the temperature of the substrate holder is at least 700° C., at least 800° C., or at least 900° C.; at most 1300° C., at most 1200° C. or at most 1100° C.; or within the range of 700° C. to 1300° C., 700° C. to 1100° C., 800° C. to 1300° C., 800° C. to 1200° C., 900° C. to 1300° C., or 900° C. to 1100° C.

In one embodiment, the temperature of the growth surface of the seed is at least 800° C., at least 900° C., or at least 1000° C.; at most 1400° C., at most 1300° C. or at most 1200° C.; or within the range of 800° C. to 1400° C., 900° C. to 1300° C., 900° C. to 1200° C., 900° C. to 1100° C., 1000° C. to 1200° C., or 1000° C. to 1100° C.

In one embodiment, the growth rate of the SCD according to the present method is at least 4 micrometre per hour (μm/hr), at least 10 μm/hr, or at least 15 μm/hr; at most 80 μm/hr, at most 70 μm/hr, or at most 60 μm/hr; or in the range of 4 to 80 μm/hr, or 10 to 70 μm/hr, or 10 to 60 μm/hr, or 15 to 60 μm/hr.

According to a further aspect of the present invention, there is provided a CVD synthesized single crystal diamond (SCD) material, the material having a truncated shape including a base, at least one truncated surface substantially parallel to the base and at least one height, the at least one height being measured between the base and the at least one truncated surface, the SCD material having at least one, at least two, or at least three of the following structural features:
a) the base of the truncated shape has a surface area of at least 16 mm², at least 25 mm², or at least 36 mm²;
b) the base of the truncated shape has a surface area of at most 400 mm², at most 225 mm², or at most 144 mm²;
c) the base of the truncated shape has a surface area within a range of 16 mm² to 400 mm², 25 mm² to 225 mm², 36 mm² to 225 mm², or 36 mm² to 144 mm²;
d) at least one truncated surface of the truncated shape has a surface area of at least 1 mm², at least 4 mm², or at least 9 mm²;
e) at least one truncated surface of the truncated shape has a surface area of at most 196 mm², at most 64 mm², or at most 25 mm²;
f) at least one the truncated surface of the truncated shape has a surface area within a range of 1 mm² to 196 mm², 9 mm² to 196 mm², or 4 mm² to 64 mm²;
g) at least one height is of 1 mm or more, 2 mm or more, or 3 mm or more;
h) at least one height is of 15 mm or less, 10 mm or less, or 5 mm or less;
i) at least one height is within the range of 1 mm to 15 mm, 2 mm to 10 mm, or 3 mm to 10 mm;
j) at least one slope formed between an edge of the base and an edge of the at least one truncated surface forms an acute angle with the base, the acute angle being of 75° or less, 70° or less, or 65° or less, for a truncated shape having a total height of 3 mm or more;
k) at least one slope formed between an edge of the base and an edge of the at least one truncated surface forms an acute angle with the base, the acute angle being of 35° or more, 40° or more, or 45° or more, for a truncated shape having a total height of 3 mm or more;
l) at least one slope formed between an edge of the base and an edge of the at least one truncated surface forms an acute angle with the base, the acute angle being in the range of 35° to 75°, or 40° to 75°, or 40° to 70°, for a truncated shape having a total height of 3 mm or more;
m) a polishing efficiency for polishing any cut diamond shape out of the truncated shape maximizing exploitation of a volume of the truncated shape, of 30% or more, 35% or more, 40% or more, or 45% or more;
n) a polishing efficiency for polishing any cut diamond shape out of the truncated shape maximizing exploitation of a volume of the truncated shape of 80% or less, 70% or less, or 60% or less;
o) a polishing efficiency for cutting a round brilliant diamond shape maximizing exploitation of a volume of the truncated shape within the range of 30% to 80%, 35% to 80%, 35% to 70%, 35% to 60%, or 40% to 60%;
p) the truncated shape includes two truncated surfaces substantially parallel to one another and to the base, the base being a common base situated between the two truncated surfaces, the truncated shape having a first height H1 between the base and a first proximal truncated surface of the two truncated surfaces and a second height H2 between the base and a second distal truncated surface of the two truncated surfaces, wherein H1 <<H2 and the height ratio of H2 to H1 is at least 2, at least 2.5, at least 3, at least 3.5, or at least 4;
q) the truncated shape includes two truncated surfaces substantially parallel to one another and to the base, the base being a common base situated between the two truncated surfaces, the truncated shape having a first height H1 between the base and a first proximal truncated surface of the two truncated surfaces and a second height H2 between the base and a second distal truncated surface of the two truncated surfaces, wherein H1 <<H2 and the height ratio of H2 to H1 is at most 15, at least 10, at most 8, or at most 6;

r) the truncated shape includes two truncated surfaces substantially parallel to one another and to the base, the base being a common base situated between the two truncated surfaces, the truncated shape having a first height H1 between the base and a first proximal truncated surface of the two truncated surfaces and a second height H2 between the base and a second distal truncated surface of the two truncated surfaces, wherein H1 <<H2 and the height ratio of H2 to H1 is within the range of 2 to 15, 2 to 10, 3 to 8, or 4 to 10;
s) the SCD material has a weight of at least 0.5 carat, at least 0.7 carat, or at least 1.0 carat;
t) a diamond polished out of the truncated shape has a gem quality as set by internationally recognized gemmological standards and is optionally colorless, near colorless, or faintly tinted, the polished diamond having a color grade on a GIA scale of M or better, L or better, or K or better, a better color grade meaning a less tinted, near colorless or colorless polished diamond; and
u) the SCD material is layer-less.

Whereas the color grading provided in t) relates to a particular subset of polished diamonds achieving gem quality standards, namely pertaining to faintly tinted to colorless diamonds, the method is additionally suitable for the manufacturing of tinted or colored diamonds, when so desired. Therefore, colored CVD grown SCDs additionally satisfying at least one, at least two or at least three of the features listed in clauses a) to s), and further meeting gem quality standard, are also contemplated and claimed. Examples of internationally recognized gemmological standards include, but are not limited, to gem quality standards as set by the Gemmological Institute of America (GIA).

In a further aspect, the SCD material having at least one, at least two, or at least three of the features listed in clauses a) to u) of previous paragraph, or a layer-less SCD material further having at least one, at least two, or at least three of the features listed in clauses a) to t) of previous paragraph, is prepared in a PECVD apparatus or system as herein disclosed.

In a further aspect, the SCD material having at least one, at least two, or at least three of the features listed in clauses a) to u) of previous paragraph, or a layer-less SCD material further having at least one, at least two, or at least three of the features listed in clauses a) to t) of previous paragraph, is prepared by a PECVD method as herein disclosed.

In one embodiment, the SCD material (optionally prepared in an apparatus, a system and/or by a method according to the present teachings) fulfils feature j), namely having at least one slope formed between an edge of the base and an edge of the at least one truncated surface forms an acute angle with the base, the acute angle being of 75° or less, 70° or less, or 65° or less, for a truncated shape having a total height of 3 mm or more. In a particular embodiment, such SCD material is furthermore layer-less according to feature u).

In one embodiment, the SCD material (optionally prepared in an apparatus, a system and/or by a method according to the present teachings) fulfils feature j), namely having at least one slope formed between an edge of the base and an edge of the at least one truncated surface forms an acute angle with the base, the acute angle being of 75° or less, 70° or less, or 65° or less, for a truncated shape having a total height of 3 mm or more; and feature k), namely, the acute angle being of 35° or more, 40° or more, or 45° or more. In a particular embodiment, such SCD material is furthermore layer-less according to feature u).

In one embodiment, the SCD material (optionally prepared in an apparatus, a system and/or by a method according to the present teachings) fulfils feature m), namely having a polishing efficiency for polishing any cut diamond shape out of the truncated shape maximizing exploitation of a volume of the truncated shape, of 30% or more, 35% or more, 40% or more, or 45% or more. In a particular embodiment, such SCD material is furthermore layer-less according to feature u).

In one embodiment, the SCD material (optionally prepared in an apparatus, a system and/or by a method according to the present teachings) fulfils feature m), namely having a polishing efficiency for polishing any cut diamond shape out of the truncated shape maximizing exploitation of a volume of the truncated shape, of 30% or more, 35% or more, 40% or more, or 45% or more; and feature n), namely the polishing efficiency being of 80% or less, 70% or less, or 60% or less. In a particular embodiment, such SCD material is furthermore layer-less according to feature u).

In one embodiment, the SCD material (optionally prepared in an apparatus, a system and/or by a method according to the present teachings) fulfils feature j), namely having at least one slope formed between an edge of the base and an edge of the at least one truncated surface forms an acute angle with the base, the acute angle being of 75° or less, 70° or less, or 65° or less, for a truncated shape having a total height of 3 mm or more; feature k), namely, the acute angle being of 35° or more, 40° or more, or 45° or more; feature m), namely having a polishing efficiency for polishing any cut diamond shape out of the truncated shape maximizing exploitation of a volume of the truncated shape, of 35% or more, 40% or more, or 45% or more; and feature n), namely the polishing efficiency being of 80% or less, 70% or less, or 60% or less. In a particular embodiment, such SCD material is furthermore layer-less according to feature u).

As known to the skilled person, in many cases the source of a rough diamond (natural or synthetic lab-grown) can be assessed by naked eye of a trained observer. Routine analytical methods exist which may further facilitate such a classification, once the rough diamonds are polished. Both rough and polished diamonds can be analysed by microscopic and spectroscopic methods (e.g., Raman spectroscopy, photoluminescence spectroscopy, cross polarizers microscopy, cathodoluminescence microscopy, etc.) in order to distinguish between the various types of diamonds (natural, HPHT and CVD). Gemmological laboratories have such equipment and routinely provide such classifications.

Referring now to FIG. 8, a plasma enhanced chemical vapour deposition (PECVD) device 800 in which the present method can be implemented is schematically illustrated. The apparatus or system comprises a microwave generator 810 configured to generate microwaves at a desired power and frequency, and a plasma chamber 820, to which the microwaves so generated are introduced. Plasma chamber 820 comprises a base 822, a top plate 824, and a side wall 826 extending from the base to the top plate defining a resonance cavity for supporting a microwave resonance mode between the base and the top plate. A plasma cloud that may be generated in operation of the apparatus or system is schematically depicted by a doted hemisphere hovering over the surface of a holder. The PECVD apparatus includes a microwave coupling configuration 830 for introducing the microwaves from the microwave generator 810 into the plasma chamber 820. A gas flow system 840 for feeding process gases into the plasma chamber and removing exhaust gases therefrom is schematically represented by ingoing and outgoing arrows 842 and 844, respectively. The substrate holder 850 comprising an outer surface 852 and at least one supporting surface 854 for supporting a substrate of single crystal diamond to serve as a seed (e.g., 856), can be constructed as previously detailed in connection with FIGS. 1 to 5, the seed supporting surface 854 being recessed with respect to the outer surface 852 of the holder. The apparatus also has a pressure regulator 860 for regulating the pressure within the plasma chamber 820 and a cooling system 870 for regulating the temperature of the substrate holder. While the pressure regulator 860 is for simplicity and clarity of the drawing represented as an arrow pointing to the plasma chamber, such regulator is typically positioned at the exhaust 844 of the process gases. Box 880 represents a control system for setting the relative rate of growth of the SCD on the seed substrate and of PCD on the surface of the holder. For instance, the controller 880 may control of at least one of the microwave power, the cooling of the substrate holder and the chemical composition of the process gases, such that a single crystal diamond is grown on the substrate so as to protrudes above the surface of the holder. As previously detailed, the growth of the SCD above the surface of the holder is constrained to reduce in cross sectional area or at least not to increase in cross sectional area with increased distance from the surface of the holder by the simultaneous growth of a PCD layer on the surface of the holder.

The PECVD apparatus or system 800 afore-described was used to implement the method according to the present teachings, and a photography of a rough diamond as obtained by the method of the invention is shown in FIG. 10. As can be seen in the image, the shape of the diamond resembles a truncated bipyramid, the truncated pyramid having grown in the recessed pocket being thinner than the truncated pyramid having grown above-the surface of the holder. The side faces of the grown rough diamond are not oriented in a specific crystallographic orientation and their orientation is defined by the growth of the surrounding polycrystalline diamond and can be at any arbitrary angle. The outlines of such an exemplary truncated shape are depicted in FIGS. 7A and 7B. FIG. 7A illustrates a perspective view of the truncated bipyramid, whereas FIG. 7B is a side view of the same. In FIG. 7B, a truncated bipyramid 700 is shown has having an upper truncated surface 710 (which protruded above holder surface during synthesis), a base 720 common to both truncated pyramids, and a lower truncated surface 730 (corresponding to the seed within the recessed pocket). The distance between the lower truncated surface 730 and the base 720 defines a first height H1 of the truncated shape 700, while the distance between the base 720 and the upper truncated surface 710 and defines a second height H2 of the truncated shape. As previously detailed, a SCD diamond lab-grown according to the present methods may also have a truncated shape corresponding to only one of the truncated pyramids (having a trapezoid cross-section), being typically similar to the upper one in the drawing.

FIGS. 11 to 14 show how finished diamonds may be polished out of rough lab-grown diamonds. FIGS. 11 and 12 relate to the preparation of a round shape diamond of about 1.3 carat (ct). FIG. 11 shows at which polishing efficiency, such a round shape diamond may be obtained from a cuboid rough diamond synthesized by conventional PECVD methods, the seed being placed on the outer surface of the holder. As shown, the polish yield in this case may be of about 31%. FIG. 12 shows at which polishing efficiency, a same round shape diamond may be obtained from a truncated shape diamond synthesized according to a PECVD method of the invention, the seed being placed in a pocket recessed into the surface of the holder. As shown, the polish yield in this case was dramatically increased to about 47%, significantly reducing the amount of waste. FIGS. 13 and 14 relate to the preparation of a cushion shape diamond of about 1.9 ct. FIG. 13 shows at which polishing efficiency, such a cushion shape diamond may be obtained from a cuboid rough diamond synthesized by conventional PECVD methods. As shown, the polish yield in this case may be of about 46%. FIG. 14 shows at which polishing efficiency, a similar cushion shape diamond may be obtained from a truncated shape diamond synthesized according to a PECVD method of the invention, the seed being placed in a recessed pocket. As shown, the polish yield in this case was dramatically increased to about 67%, significantly reducing the amount of waste. The commercial value of this markedly improved efficiency of transformation of rough diamonds into finished ones can readily be appreciated and need not be further emphasized.

While various aspects and embodiments of the present invention were described in connection with CVD apparatus, system and/or method wherein the plasma comprising the carbon species is generated by a microwave, this should not be construed as limiting the scope of the invention. A skilled person can readily appreciate that DC plasma CVD (in which plasma is generated by DC voltage), Toroidal plasma enhanced CVD (in which plasma is generated by inductively coupled AC voltage), and Hot Filament CVD (in which the molecules of the process gases are excited by a hot filament), to name a few, can alternatively serve in the implementation of the invention and are encompassed therein.

While, for the sake of illustration, this disclosure has been described in terms of certain embodiments and generally associated methods, alterations and permutations of the embodiments and methods will be apparent to those skilled in the art based upon Applicant's disclosure herein. The present disclosure is to be understood as not limited by the specific embodiments described herein. It is intended to embrace all such alternatives, modifications and variations and to be bound only by the spirit and scope of the disclosure and any change which come within their meaning and range of equivalency.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. Certain features described in the context of various embodiments are not to be considered essential features of those embodiments, unless the embodiment is inoperative without those elements.

Unless otherwise stated, the use of the expression “and/or” between the last two members of a list of options for selection indicates that a selection of one or more of the listed options is appropriate and may be made.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

In the disclosure, unless otherwise stated, adjectives such as “substantially”, “approximately” and “about” that modify a condition or relationship characteristic of a feature or features of an embodiment of the present technology, are to be understood to mean that the condition or characteristic is defined to within tolerances that are acceptable for operation of the embodiment for an application for which it is intended, or within variations expected from the measurement being performed and/or from the measuring instrument being used. When the terms “about” and “approximately” precede a numerical value, it is intended to indicate +/−15%, or +/−10%, or even only +/−5%, and in some instances the precise value. Furthermore, unless otherwise stated, the terms (e.g., numbers) used in this disclosure, even without such adjectives, should be construed as having tolerances which may depart from the precise meaning of the relevant term but would enable the invention or the relevant portion thereof to operate and function as described, and as understood by a person skilled in the art.

In the description and claims of the present disclosure, each of the verbs “comprise”, “include” and “have”, and conjugates thereof, are used to indicate that the object or objects of the verb are not necessarily a complete listing of features, members, steps, components, elements or parts of the subject or subjects of the verb.

As used herein, the singular form “a”, “an” and “the” include plural references and mean “at least one” or “one or more” unless the context clearly dictates otherwise. At least one of A and B is intended to mean either A or B, and may mean, in some embodiments, A and B.

Positional or motional terms such as “upper”, “lower”, “right”, “left”, “bottom”, “below”, “lowered”, “low”, “top”, “above”, “elevated”, “high”, “vertical”, “horizontal”, “backward”, “forward”, “upstream” and “downstream”, as well as grammatical variations thereof, may be used herein for exemplary purposes only, to illustrate the relative positioning, placement or displacement of certain components, to indicate a first and a second component in present illustrations or to do both. Such terms do not necessarily indicate that, for example, a “bottom” component is below a “top” component, as such directions, components or both may be flipped, rotated, moved in space, placed in a diagonal orientation or position, placed horizontally or vertically, or similarly modified.

Unless otherwise stated, when the outer bounds of a range with respect to a feature of an embodiment of the present technology are noted in the disclosure, it should be understood that in the embodiment, the possible values of the feature may include the noted outer bounds as well as values in between the noted outer bounds.

I claim:

1. A method of manufacturing lab grown diamond material by plasma enhanced chemical vapour deposition (PECVD), which comprises:
placing in a recessed pocket of a holder located in a chemical vapour deposition chamber a single crystal diamond substrate to act as a seed,
establishing within the chamber a plasma containing carbon species, by introducing process gases into the chamber and heating the gases by electrically generated energy, to cause carbon to be deposited as a single crystal diamond (SCD) on the substrate to form a lab grown diamond and in polycrystalline diamond (PCD) form on the substrate holder,
growing SCD on the substrate sufficiently to cause a part of the lab grown diamond to protrude from the pocket, and
setting the relative rate of growth of the SCD on the substrate and the PCD on the surface of the holder, by control of at least one of (i) an applied energy, (ii) cooling of the substrate holder and (iii) a chemical composition of the process gases, such that the PCD layer is grown on the surrounding surface of the holder at such a rate as to lie, at all times, at a height above the surface of the recessed pocket in the holder that is at least as high as the surface of the SCD, whereby the PCD layer entirely surrounds the SCD grown on the substrate and constrains lateral growth of the SCD to prevent an increase of a cross-sectional area of a part of the lab grown diamond protruding out of the recessed pocket.

2. A method as claimed in claim 1, wherein the constraining of the lateral growth of the single crystal diamond results in a reduction in the cross-sectional area of the part of the single crystal diamond protruding out of the recessed pocket with increasing distance from the holder.

3. A method as claimed in claim 1, wherein the constraining of the lateral growth of the single crystal diamond is such that the height of the synthesised single crystal diamond, as measured from the substrate, is between 40% and 80% of the maximum width of the substrate.

4. A method as claimed in claim 1, wherein the energy is applied in the form of electromagnetic (EM) energy at a frequency in the microwave range, i.e. having a wavelength between 1 mm and 1 m.

5. A method as claimed in claim 1, wherein the process gases include at least a source of carbon atoms and hydrogen atoms, the process gases being optionally selected from a group comprising H₂, CH₄, C₂H₂, C₂H₄, C₂H₆, O₂, CO₂, N₂, NO₂, N₂O, Ar, and combinations thereof.

6. A PECVD system for manufacturing a lab grown single crystal diamond (SCD) material via chemical vapour deposition, the system comprising:
a. a microwave generator configured to generate microwaves at a frequency f;
b. a plasma chamber comprising a base, a top plate, and a side wall extending from said base to said top plate defining a resonance cavity for supporting a microwave resonance mode between the base and the top plate;
c. a microwave coupling configuration for introducing microwaves from the microwave generator into the plasma chamber;
d. a gas flow system for feeding process gases into the plasma chamber and removing exhaust gases therefrom, the gas flow system including a gas flow controller for controlling a composition of the process gases;
e. a substrate holder disposed in the plasma chamber and comprising an outer surface and at least one supporting surface for supporting the seed, the surface supporting the seed being recessed with respect to the outer surface of the holder;
f. a pressure control system for regulating the pressure within the plasma chamber;
g. a cooling system for regulating the temperature of the substrate holder; and
h. a control system for setting a relative rate of growth of the SCD on the substrate and a polycrystalline diamond (PCD) layer on the surface of the holder, by control of at least one of (i) an applied energy, (ii) cooling of the substrate holder and (iii) a chemical composition of the process gases, such that the PCD layer is grown on the surrounding surface of the holder at such a rate as to lie, at all times, at a height above the surface of the recessed pocket in the holder that is at least as high as the surface of the SCD, whereby the PCD layer entirely surrounds the SCD grown on the substrate and constrains lateral growth of the SCD so as to prevent an increase in cross sectional area of the part of the lab grown diamond protruding from the recessed pocket.

7. A PECVD system as claimed in claim 6, wherein the control system is operative to set the relative rate of growth of the SCD on the substrate and of the PCD layer on the surface of the holder in such a manner that the SCD is laterally constrained by the surrounding PCD layer to cause the cross sectional area of the part of the single crystal diamond protruding beyond the recessed surface of the holder to decrease with increasing distance from the holder.

8. A CVD synthesized lab grown single crystal diamond (SCD) material, the SCD material upon completion of chemical vapour deposition having a first shape of which the cross sectional area decreases, or does not increase, with increasing distance from a flat base formed by a surface of a seed from which the SCD material is grown and having a truncated surface substantially parallel to the base, or a second shape having the form of a two back to back truncated tapered shapes that share a common base, the seed from which the SCD material is grown forming a flat truncated surface of one of the two truncated tapered shapes.

9. A CVD synthesized lab grown SCD material as claimed in claim 8, wherein the first shape is, or the back-to-back truncated tapered shapes are each, a truncated pyramid having a polygon base and truncated surface.

10. A CVD synthesized lab grown SCD material as claimed in claim 8, wherein the first shape, or at least one of the two truncated tapered shapes, has a height, measured between the base or common base and the truncated surface, the lab grown SCD material having any one, any two, any three, or all four of the following structural features:
a) at least one height is of 1 mm or more, 2 mm or more, or 3 mm or more;
b) at least one height is of 15 mm or less, or 10 mm or less, or 5 mm or less;
c) at least one height is within the range of 1 mm to 15 mm, 2 mm to 10 mm, or 3 mm to 10 mm; and
d) being layer-less.

11. A CVD synthesized lab grown SCD material as claimed in claim 8, the lab grown SCD material having any one, any two, any three, or all four of the following structural features:
a) the base of the first shape or the common base of the two truncated tapered shapes has a surface area of at least 16 mm², at least 25 mm², or at least 36 mm²;
b) the base of the first shape or the common base of the two truncated tapered shapes has a surface area of at most 400 mm², at most 225 mm², or at most 144 mm²;
c) the base of the first shape or the common base of the two truncated tapered shapes has a surface area within a range of 16 mm² to 400 mm², 25 mm² to 225 mm², 36 mm² to 225 mm², or 36 mm² to 144 mm²; and
d) being layer-less.

12. A CVD synthesized lab grown SCD material as claimed in claim 8, the lab grown SCD material having any one, any two, any three, or all four of the following structural features:
a) at least one truncated surface of the first shape or of the two truncated tapered shapes has a surface area of at least 1 mm², at least 4 mm², or at least 9 mm²;
b) at least one truncated surface of the first shape or of the two truncated tapered shapes has a surface area of at most 196 mm², at most 64 mm², or at most 25 mm²;
c) at least one truncated surface of the first shape or of the two truncated tapered shapes has a surface area within a range of 1 mm² to 196 mm², 9 mm² to 196 mm², or 4 mm² to 64 mm²; and
d) being layer-less.

13. A CVD synthesized lab grown SCD material as claimed in claim 8, the lab grown SCD material having any one, any two, any three, or all four of the following structural features:
a) at least one slope formed between an edge of the base or common base and an edge of the at least one truncated surface forms an acute angle with the base or common base, the acute angle being of 75° or less, 70° or less, or 65° or less, for a first shape or one of the two truncated tapered shapes having a height of 3 mm or more;
b) at least one slope formed between an edge of the base or common base and an edge of the at least one truncated surface forms an acute angle with the base or common base, the acute angle being of 35° or more, 40° or more, or 45° or more, for a first shape or one of the two truncated tapered shapes having a height of 3 mm or more;
c) at least one slope formed between an edge of the base or common base and an edge of the at least one truncated surface forms an acute angle with the base or common base, the acute angle being in the range of 35° to 75°, or 40° to 75°, or 40° to 70°, for a first shape or one of the two truncated tapered shapes having a height of 3 mm or more; and
d) being layer-less.

14. A CVD synthesized lab grown SCD material as claimed in claim 8, wherein the lab grown SCD material has the form of two back to back truncated tapered shapes sharing a common base, a first truncated tapered shape having a first height H1 between the common base and a first proximal truncated surface, and a second truncated tapered shape having a second height H2 between the common base and a second distal truncated surface, wherein H1 <<H₂, the truncated tapered shapes of the lab grown SCD material having any one, any two, any three, or all four of the following structural features:
a) the height ratio of H2 to H1 is at least 2, at least 2.5, at least 3, at least 3.5, or at least 4;
b) the height ratio of H2 to H1 is at most 15, at least 10, at most 8, or at most 6;
c) the height ratio of H2 to H1 is within the range of 2 to 15, 2 to 10, or 4 to 10; and
d) being layer-less.

15. A CVD synthesized lab grown SCD material as claimed in claim 8, the lab grown SCD material having any one, any two, or any three or more of the following structural features:
a) a polishing efficiency for polishing any cut diamond shape out of the first shape or two truncated tapered shapes maximizing exploitation of a volume of the first shape or two truncated tapered shapes, of 30% or more, 35% or more, 40% or more, or 45% or more;
b) a polishing efficiency for polishing any cut diamond shape out of the first shape or two truncated tapered shapes maximizing exploitation of a volume of the first shape or two truncated tapered shapes of 80% or less, 70% or less, or 60% or less;
c) a polishing efficiency for cutting a round brilliant diamond shape maximizing exploitation of a volume of the first shape or two truncated tapered shapes within the range of 30% to 80%, 35% to 80%, 30% to 70%, 35% to 70%, 30% to 60%, 35% to 60%, or 40% to 60%;
d) the lab grown SCD material has a weight of at least 0.5 carat, at least 0.7 carat, or at least 1.0 carat;
e) a diamond polished out of the first shape or two truncated tapered shapes meets gem quality standards and is optionally colorless, near colorless, or faintly tinted, the polished diamond having a color grade on a GIA scale of M or better, L or better, or K or better, a better color grade meaning a less tinted, near colorless or colorless polished diamond; and
f) the lab grown SCD material is layer-less.

16. A CVD synthesized lab grown SCD material as claimed in claim 8, the lab grown SCD material having side faces in a crystallographic orientation other than {100}, {110}, 11111, and {113}.

17. A diamond material comprising at least one CVD synthesized lab grown single crystal diamond (SCD) material formed by chemical vapour deposition on a surface of at least one seed, the SCD material grown on each seed being surrounded by a polycrystalline diamond (PCD) material on all lateral faces, the SCD material grown on each seed having either a first shape of which the cross sectional area decreases, or does not increase, with increasing distance from the respective surface of the seed and having a truncated surface substantially parallel to the base, or a second shape formed of two back to back truncated tapered shapes that share a common base, the seed from which the SCD material is grown forming a flat truncated surface of one of the two truncated tapered shapes.

18. A diamond material comprising at least one CVD synthesized lab grown SCD material surrounded by the PCD material as claimed in claim 17, wherein the first shape of the CVD synthesized lab grown SCD material on each seed is, or the back-to-back truncated tapered shapes are each, a truncated pyramid having a polygon base and truncated surface.

19. A diamond material comprising at least one CVD synthesized lab grown SCD material surrounded by the PCD material as claimed in claim 17, wherein the first shape, or at least one of the two back-to-back truncated tapered shapes, of the CVD synthesized lab grown SCD material on each seed has a height, measured between the base or common base and the truncated surface, the respective lab grown SCD material having any one, any two, or any three or more of the following structural features:
a) at least one height is of 1 mm or more, 2 mm or more, or 3 mm or more;
b) at least one height is of 15 mm or less, or 10 mm or less, or 5 mm or less;
c) at least one height is within the range of 1 mm to 15 mm, 2 mm to 10 mm, or 3 mm to 10 mm;
d) the base of the first shape or the common base of the two truncated tapered shapes has a surface area of at least 16 mm², at least 25 mm², or at least 36 mm²;
e) the base of the first shape or the common base of the two truncated tapered shapes has a surface area of at most 400 mm², at most 225 mm², or at most 144 mm²;
f) the base of the first shape or the common base of the two truncated tapered shapes has a surface area within a range of 16 mm² to 400 mm², 25 mm² to 225 mm², 36 mm² to 225 mm², or 36 mm² to 144 mm²;
g) at least one truncated surface of the first shape or of the two truncated tapered shapes has a surface area of at least 1 mm², at least 4 mm², or at least 9 mm²;
h) at least one truncated surface of the first shape or of the two truncated tapered shapes has a surface area of at most 196 mm², at most 64 mm², or at most 25 mm²;
i) at least one truncated surface of the first shape or of the two truncated tapered shapes has a surface area within a range of 1 mm² to 196 mm², 9 mm² to 196 mm², or 4 mm² to 64 mm²;
j) at least one slope formed between an edge of the base or common base and an edge of the at least one truncated surface forms an acute angle with the base or common base, the acute angle being of 75° or less, 70° or less, or 65° or less, for a first shape or one of the two truncated tapered shapes having a height of 3 mm or more;
k) at least one slope formed between an edge of the base or common base and an edge of the at least one truncated surface forms an acute angle with the base or common base, the acute angle being of 35° or more, 40° or more, or 45° or more, for a first shape or one of the two truncated tapered shapes having a height of 3 mm or more;
l) at least one slope formed between an edge of the base or common base and an edge of the at least one truncated surface forms an acute angle with the base or common base, the acute angle being in the range of 35° to 75°, or 40° to 75°, or 40° to 70°, for a first shape or one of the two truncated tapered shapes having a height of 3 mm or more; and
m) being layer-less.

20. A diamond material comprising at least one CVD synthesized lab grown SCD material surrounded by the PCD material as claimed in claim 17, wherein the lab grown SCD material of the at least one CVD synthesized lab grown SCD material has the form of two back to back truncated tapered shapes sharing a common base, a first truncated tapered shape having a first height H1 between the common base and a first proximal truncated surface, and a second truncated tapered shape having a second height H2 between the common base and a second distal truncated surface, wherein H1<<H₂, the truncated tapered shapes of the lab grown SCD material having any one, any two, any three, or all four of the following structural features:
a) the height ratio of H2 to H1 is at least 2, at least 2.5, at least 3, at least 3.5, or at least 4;
b) the height ratio of H2 to H1 is at most 15, at least 10, at most 8, or at most 6;
c) the height ratio of H2 to H1 is within the range of 2 to 15, 2 to 10, or 4 to 10; and
d) the lab grown SCD material being layer-less.
